(19) United States
(12) Patent Application Publication
(10) Pub. No.: US 2009/0032720 A1
(43) Pub. Date: Feb. 5, 2009

(54) SYSTEM WITH OPTICAL ENERGY PRODUCING STRUCTURE AND ELECTRICAL DEVICE COMPRISING SOLAR CELL

(76) Inventor: Lee ATKINSON, Taipei (TW)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/830,562

(22) Filed: Jul. 30, 2007

(51) Int. Cl. H01L 31/04; G21G 4/04

(52) U.S. Cl. 250/393; 250/336.1; 250/503.1; 250/504 R

(57) ABSTRACT

A system comprises an optical energy producing structure that produces non-visible light and an electrical device comprising a solar cell that faces the structure when the electrical device rests on the structure. The solar cell converts non-visible light from the structure to electrical energy for use by the electrical device. The structure comprises a cover that is substantially transparent to the non-visible light, but is substantially opaque to visible light. The electrical device receives the non-visible light through the cover.

### BACKGROUND

Many electrical devices are battery-powered. Many of such device use rechargeable batteries. Recharging a battery is inconvenient to a user of such a device.

### BRIEF DESCRIPTION OF THE DRAWINGS

For a detailed description of exemplary embodiments of the invention, reference will now be made to the accompanying drawings in which:

FIG. 1 shows a partially exploded view of a system in accordance with various embodiments;

FIG. 2 shows an electrical device usable in the system of FIG. 1 in accordance with various embodiments; and

FIG. 3 shows another view of the electrical device in accordance with various embodiments.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection.

### DETAILED DESCRIPTION

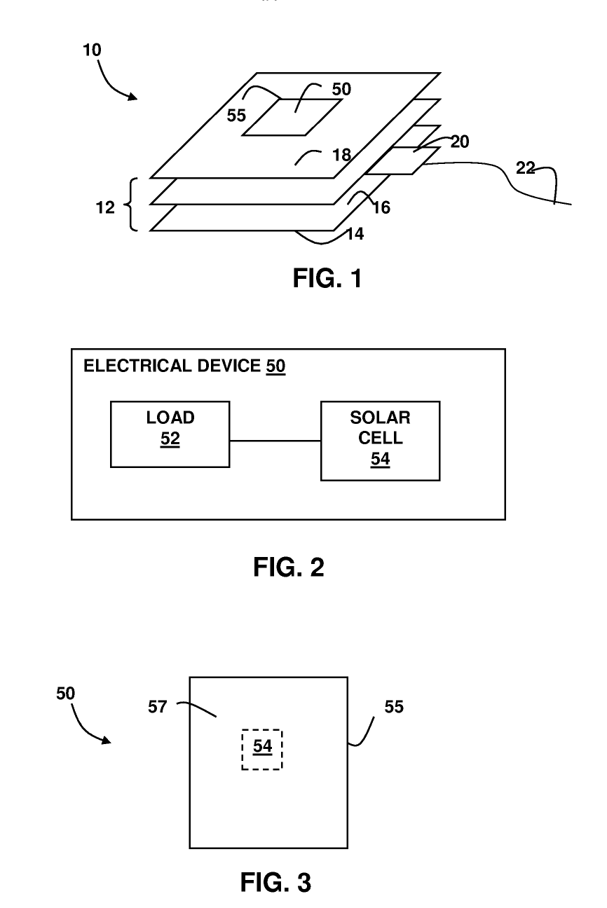

FIG. 1 illustrates a partially exploded view of a system 10 in accordance with various embodiments. As shown, system 10 comprises an optical energy producing structure 12 and an electrical device 50. The electrical device 50 rests on or near the optical energy producing structure 12. In at least some embodiments, the optical energy producing structure 12 produces non-visible light that is received and used by the electrical device 50. In some embodiments, the non-visible light is received by the electrical device 50, which converts such light to electrical energy for use in powering an operational circuit and/or charging a rechargeable battery. In various embodiments, the energy received by the electrical device 50 from the optical energy producing structure 12 is not by way of electromagnetic induction.

In FIG. 1, the optical energy producing structure 12 comprises a light guide 16 provided (e.g., sandwiched) between a reflector 14 and a cover 18. The three components of the structure 12 may be adhered to one another using an adhesive or other suitable form of attachment. A light source 20 is also provided and is optically coupled to the light guide 16. The light source 20 produces non-visible light (i.e., light that has no substantial component in the visible portion of the spectrum). In some embodiments, the light source 20 produces infra-red light (light having a wavelength from about 700 nm to about 1000 nm), while in other embodiments, the light source 20 produces ultra-violet light (light having a wavelength from about 200 nm to about 400 nm). In at least embodiments, the optical energy produced by the light source 20 comprises no more than 10% visible light (visible light is light having a wavelength from about 400 nm to about 700 nm).

The light guide 16 functions to disperse the non-visible light received from the light source 20 substantially evenly across the surface of the light guide 16. In some embodiments, the light guide 16 is made from Polymethyl Methacrylate (PMMA).

The reflector 14 comprises a material that generally reflects the non-visible light produced by the light source 20. As such, a substantial amount (e.g., 90% or more) of the light produced by the light source 20 is channeled up through the cover 18. The cover 18 is substantially transparent to the non-visible light produced by the light source 20 (permits at least 90% of the non-visible light produced by the light source 20 to pass through), but is substantially opaque to visible light (blocks at least 90% of visible light). As such, a user generally cannot see the light guide 16 and/or reflector 14 through the cover 18. In various embodiments, the cover 18 is made from tinted PMMA.

The electrical device 50 comprises a housing 55 that contains, as such illustrated in FIG. 2, a load 52 coupled to a solar cell 54. The load 52 comprises an operational circuit and/or a rechargeable battery. Such an operational circuit enables the electrical device 50 to perform its intended function. The load 52, and thus electrical device 50, can perform any of a variety of functions. The solar cell 54 is sensitive to the non-visible light produced by the light source 20. As such, the solar cell 54 receives and converts such non-visible light to electrical energy for use by the load, for example, to power an operational circuit and/or charge a battery.

In accordance with various embodiments, at least one surface of the electrical device's housing 55 is substantially transparent (permits at least 90% of the non-visible light produced by the light source 20 to pass through) to the non-visible light received by the light source 20, but is substantially opaque to visible light (blocks at least 90% of visible light). As such, a user generally cannot see the internal components (e.g., load 52, solar cell 54) through such a surface. In various embodiments, the cover 18 is made from tinted PMMA. FIG. 3 illustrates a bottom view of the electrical device 50. The housing 55 of the electrical device comprises a bottom surface 57 that is substantially transparent to the non-visible light received by the light source 20, but substantially opaque to visible light.

At least one use for system 10 is to power a computer mouse, or recharge the mouse's battery. In such embodiments, the optical energy producing structure 12 comprises a mouse pad. The electrical device 50 comprises a pointing device (e.g., mouse) for use by a user to operate a computer. The light source 20 may be electrically connected to the computer by way of conductor 22. Electrical power is provided by the computer over conductor 22 to the light source 20 for powering the light source. The solar cell of the mouse (electrical device 50) faces the cover 18 of the mouse pad (structure 12) when the mouse rests on the mouse pad.

In some embodiments, the optical energy producing structure 12 comprises a feature whereby the presence of the electrical device 50 can be detected. If the electrical device 50 is not detected as being present on structure 12, the light source 20 can be turned off. If, on the other hand, the electrical device 50 is detected as being present on structure 12, the light source 20 can be turned on to wirelessly provide power to the load 52. In some embodiments, the mechanism by which the structure detects the presence of the electrical device comprises a magnet provided in electrical device 50 and a magnetic sensor provided in optical energy producing structure 12.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system, comprising:
an optical energy producing structure that produces non-visible light; and
an electrical device comprising a solar cell that faces said structure when said electrical device rests on said structure, said solar cell converts non-visible light from said structure to electrical energy for use by said electrical device; and
wherein said structure comprises a cover that is transparent to said non-visible light, but is opaque to visible light, and said electrical device receiving said non-visible light through said cover.

2. The system of claim 1 wherein said electrical device comprises a pointing device adapted to operate a computer.

3. The system of claim 1 wherein said light source produces light selected from a group consisting of infra-red and ultra-violate light.

4. The system of claim 3 wherein said solar cell of said electrical device converts said infra-red or ultra-violet light to electrical energy.

5. The system of claim 1 wherein said solar cell of said electrical device converts said non-visible light to electrical energy for powering a circuit in said electrical device.

6. The system of claim 1 wherein said solar cell of said electrical device converts said non-visible light to electrical energy for charging a battery in said electrical device.

7. The system of claim 1 wherein said structure comprises a reflector.

8. The system of claim 1 wherein said structure comprises a light guide.

9. The system of claim 1 wherein said structure comprises a light guide provided between a cover and a reflector, said cover being transparent to said non-visible light produced by said light source, but opaque to visible light.

10. The system of claim 1 wherein said electrical device comprises a housing at least a portion of which is transparent to said non-visible light produced by said light source, but is opaque to visible light.

11. The system of claim 1 wherein said cover comprises polymethyl methacrylate.

12. An electrical device, comprising:
a solar cell that is adapted to convert non-visible light to electrical energy;
a load that receives said electrical energy from said solar cell; and
a housing that contains said solar cell and said circuit, wherein a surface of said housing is transparent to said non-visible light, but opaque to visible light, said solar cell receiving said non-visible light through said surface of said housing.

13. The electrical device of claim 12 wherein said load comprises a rechargeable battery.

14. The electrical device of claim 13 wherein said rechargeable battery is recharged with said electrical energy.

15. The electrical device of claim 12 wherein said load is powered by said electrical energy and said load enables a user of said electrical device to use said electrical device as a pointing device to control a computer.

16. An apparatus, comprising:
a light source that produces non-visible light;
a surface that is transparent to said non-visible light, but is opaque to visible light.
a light guide that distributes said non-visible light across said surface.

17. The apparatus of claim 16 wherein said light source produces light selected from a group consisting of infra-red and ultra-violate light.

18. The apparatus of claim 16 further comprising a reflector.

19. The apparatus of claim 16 wherein said surface is adapted to receive an electrical device said non-visible light being usable by said electrical device.

20. The apparatus of claim 16 further comprising a magnetic sensor that detects the presence of an electrical device on said surface.
